(19) United States
(12) Patent Application Publication
(10) Pub. No.: US 2010/0126586 A1
(43) Pub. Date: May 27, 2010

(54) PHOTOVOLTAIC DEVICE WITH SPACE-SEPARATED QUANTUM CUTTING

(75) Inventors: Dolf Timmerman, Hoorn (NL); Tomasz Gregorkiewicz, Amstelveen (NL)

Correspondence Address: WESTMAN CHAMPLIN & KELLY, P.A., SUITE 1400, 900 SECOND AVENUE SOUTH, MINNEAPOLIS, MN, 55402, US

(73) Assignee: University of Amsterdam, Amsterdam (NL)

(21) Appl. No.: 12/275,853

(22) Filed: Nov. 21, 2008

(51) Int. Cl. H01L 31/028; H01L 31/02

(52) U.S. Cl. 136/261; 136/252; 977/774

(57) ABSTRACT

A photovoltaic device is provided comprising an energy conversion material. The energy conversion material comprises nanosized semiconductor quantum structures comprising a first quantum dot and a second quantum dot. The first quantum dot has a first size, and the second quantum dot has a second size. The separation of the first and second quantum dots is of the same order of magnitude as the first or second size or smaller, such that, by irradiating the first quantum dot with a photon for producing one or more excitons in the first quantum dot, one or more further excitons are also produced in the second quantum dot.

### BACKGROUND

The discussion below is merely provided for general background information and is not intended to be used as an aid in determining the scope of the claimed subject matter.

One of the major problems in photovoltaic devices is the large range of wavelengths over which energy conversion has to take place. As an example, a solar cell must work well in the visible range, where most of the energy is available, but should also be able to convert the ultraviolet (UV) and infrared (IR) parts of the spectrum, which nevertheless contain a substantial fraction of the solar energy. Effective harvesting of energy from UV and IR photons is a necessary condition for improving the efficiency of solar cells and to reduce the cost per watt. On the lower energy side, conversion is limited by the bandgap, E_{g}, below which photon absorption is not possible. On the other side of the spectrum, for high-energy photons, a substantial part of the incoming photon energy hv is often wasted in the conversion between a photon and an electron or hole, as the energy excess represented by hv-E_{g} is transformed into kinetic energy of a generated electron-hole pair, and subsequently converted to heat. Thus, a bandgap-optimized p-n junction (‘first generation’) solar cell is a ‘one-electron-hole-pair-for-one-photon device’, with an efficiency limited to about 30%—the Shockley-Queisser limit—for a bandgap of 1.1 electron volts (eV), close to that of silicon. Even modern (organic) materials and device designs, such as thin-film devices (‘second generation’), or Grätzel cells of blended hole-transporting and electron-transporting materials (‘third generation’), cannot avoid this theoretical limit. Stacked layers (tandem devices, ‘fourth generation’) with the bandgap of each layer optimized for a specific wavelength can increase the efficiency of a device, but also increase the complexity and cost of the device.

A similar situation arises in light-emitting devices. Ideally, these should generate photons only in a particular range, such as the visible range, but existing devices often emit in a much wider spectrum (for example, fluorescent lamps). By using fluorescence, the energy of the emitted UV photons can be reduced to the visible range, but in this case, in the ‘one-photon-for-one-photon’ down-conversion, a large part of the photon energy is lost.

### SUMMARY

For photovoltaic applications it is therefore important to develop a scheme that allows the use of the excess energy that would otherwise be wasted in conversion.

An elegant solution is to use photon down-conversion or quantum cutting. This process involves the transformation of a high-energy photon into two (or more) photons of lower energy, hence ‘cutting’ the energy quantum. Ideally, the down-converted photons are in a suitable range of the spectrum and can be further used without loss of energy. Such quantum cutting may be used in rare-earth systems and in fluorescent tubes. A similar idea involves the generation of multiple electron-hole pairs by a single high-energy photon absorbed in a nanocrystal (NC). This process, termed multiple exciton generation (MEG) or carrier multiplication (CM), may be observed in nanocrystals made from different semiconductor materials, including generation of a remarkable seven excitons for a single incoming photon. The same phenomenon may also be observed in colloidal silicon nanocrystals. However, the lifetimes of multiexcitons in an nanocrystal are very short (50-100 ps and shorter, depending on the material and nanocrystal size) owing to the enhanced Auger recombination and subsequent fast carrier cooling. Therefore, harvesting of this energy—by means of carrier extraction or light generation—is difficult, as only the ‘last’ exciton has a relatively long lifetime and is usable.

A photovoltaic device is provided herein that improves ways of utilizing and harvesting optical energy and addresses the above-mentioned problems and effects, among various advantageous features. A photovoltaic device comprises an energy conversion material which comprises nanosized semiconductor quantum structures comprising a first quantum dot and a second quantum dot. The first quantum dot has a first size, and the second quantum dot has a second size. The separation of the first and second quantum dots is of the same order of magnitude as the first or second size or smaller, such that, by irradiating the first quantum dot with a photon for producing one or more excitons in the first quantum dot, one or more further excitons are also produced in the second quantum dot.

Such a device is capable of cutting the photon energy of a single photon incident on the material in portions and redistributing the energy portions over the two quantum dots.

Accordingly, a method of converting optical energy is provided which makes use of an energy conversion material comprising nanosized semiconductor quantum structures comprising a first quantum dot and a second quantum dot, the first quantum dot having a first band gap, and the second quantum dot having a second band gap. The method comprises the step of irradiating the first quantum dot with a photon having a photon energy of at least the sum of the first band gap and the second band gap to produce a first exciton in the first quantum dot and a second exciton in the second quantum dot.

Interaction between excitons in separate quantum dots, in particular destructive interaction leading to quenching of excitons, is substantially absent. Hence, an exciton in a separate quantum dot is significantly longer-lived than in case of multiple excitons within one quantum dot. Thus, the excitons may survive to be de-excited by emitting a photon or to be separated into substantially independent charge carriers. A photon thus produced has a different photon energy from the original incident photon and may be utilized for further optical effects, e.g. exciting another energy conversion material of a photovoltaic device. Charge carriers thus produced may be utilized for collecting a current.

A semiconductor material with an indirect bandgap may advantageously be chosen for the semiconductor quantum structures, since the required phonon-interaction for cooling the exciton prior to de-excitation further tends to extend the average lifetime of an exciton within the quantum dot, further facilitating harvesting the exciton energy.

For increasing the usefulness of the device, the nanosized semiconductor quantum structures may have structure sizes of the same order of magnitude, and the nanosized semiconductor quantum structures may be mutually separated by an average distance being of the same order of magnitude of the structure sizes or smaller. Suitable sizes of the quantum nanosized semiconductor quantum structures may depend on the material properties.

In general, the size of the quantum dot should be of about the same order of magnitude as or smaller than the diameter of an exciton in bulk material of the same material, given by the Bohr radius of the exciton. Typical sizes are about 8 nm diameter of smaller for silicon (Si) and about 35 nm or smaller for germanium (Ge) nanocrystals.

In an advantageous embodiment the energy conversion material comprises nanosized semiconductor quantum structures comprising quantum dots dispersed throughout at least a portion of the energy conversion material at a density of more than about 10¹⁶ cm⁻³, preferably more than about 10¹⁷ cm⁻³, or even more than about 10¹⁸ cm⁻³; the higher the concentration, the more efficient the process may be. The minimum and/or optimum concentration and thus the separation of adjacent quantum structures may be dependent on a material hosting the quantum structures.

In such a device, by irradiating a first quantum dot of said quantum dots with a photon for producing one or more excitons in said first quantum dot, one or more further excitons are likely also produced in an adjacent second quantum dot of said quantum dots.

The energy conversion material may comprise semiconductor nanocrystals, which may efficiently absorb optical energy for generation of an exciton.

The nanocrystals may be silicon (Si), which is ubiquitous, has well known properties and may be processed with well known techniques. Another suitable material is germanium (Ge). Semiconductor nanocrystals may efficiently be arranged in silicon oxide, which provides a suitable carrier for insulating adjacent nanocrystals. Si nanocrystals may be produced directly in silicon oxide.

The energy conversion material may comprise a plurality of layers, at least one of the layers comprising the nanosized semiconductor quantum structures. The energy conversion material may further comprise one or more conductive or semiconductive layers for transporting charge carriers and/or optical energy conversion layers such as photovoltaic layers, advantageously comprising an optical absorption characteristic such as a band gap suitable for absorbing optical energy from photons emitted by the quantum dots.

One or more of the layers, in particular one or more of the energy conversion layers, may comprise conductive material for improving extraction of charge carriers from the layer. Suitable conductive material may be conductive nanostructures such as carbon nanorods, for example, which may provide conduction while exhibiting relatively little optical absorption, reflection or otherwise blocking of light. Thus, extraction of charge carriers is improved while optical performance is substantially unaffected. A device in accordance with this may obviate one or more dedicated electrode layers, such as an anode layer or a cathode layer, covering a significant portion of the device.

An optimum thickness of the energy conversion material layer may depend on the material properties of the semiconductor quantum structures and host-material(s) that are used, as well as the power and nature of the incident light. For silicon nanocrystals in silicon oxide a suitable layer thickness may be from about 10-20 micrometers, to about 1 to 2 micrometers, for example. For some applications a thinner layer, of a few hundred nanometers or even less may be preferred, reducing the available number of quantum structures in the direction of the thickness of the layer. A thinner layer may facilitate harvesting charge carriers and/or emitted photons from the layer.

For tailoring the characteristics of at least one of the first and second quantum dots with respect to optical absorption, photon emission and/or energy levels and energy bands, at least one of the first size and the second size is configured for providing energy levels corresponding to a desired photon energy. E.g., the photon absorption and/or emission of a quantum dot may be tuned to lie in a particular portion of the optical wavelengths, advantageously corresponding to the spectrum of the incident light and/or corresponding to absorption characteristics of a further photovoltaic energy conversion material such as may be present in another layer in the device. Different layers of a device comprising layers may comprise nanosized semiconductor quantum structures of different materials, sizes and/or densities, e.g. for optimized acceptance and/or emission of photons at different wavelengths, allowing optimizing energy conversion for incident light with particular spectral composition such as having a very broad frequency range or having an inhomogeneous spectral power distribution with significantly higher power at some wavelengths than at other wavelengths.

It should be noted that within the framework of this disclosure, the term “optical wavelength” should be construed to denote any wavelength from at least far-infrared to far-ultraviolet, e.g. about 10 μm to about 150 nm, equivalent to a photon energy of about 0.1 eV to over 8 eV. The term “semiconductor quantum structure” is meant also to comprise combinations of semiconductors and semiconductor-metal combinations such as, but not limited to, cadmium selenide (CdSe) and lead selenide (PbSe), as illustrative examples.

For harvesting the optical energy of the incident photon or photons in the form of electricity, at least one of said first and second excitons may be separated into charge carriers, such as an electron and/or a hole, and a current generated by said charge carriers may be collected or stored between an anode and a cathode, for energy storage in a battery or operating a further device. Accordingly, the present photovoltaic device may further comprise an anode, a cathode and means for collecting charge carriers, for example a battery or a capacitor, connected to said anode and said cathode.

This Summary and the Abstract herein are provided to introduce a selection of concepts in a simplified form that are further described below in the Detailed Description. This Summary and the Abstract are not intended to identify key features or essential features of the claimed subject matter, nor are they intended to be used as an aid in determining the scope of the claimed subject matter. The claimed subject matter is not limited to implementations that solve any or all disadvantages noted in the Background.

The disclosure will hereafter be more fully explained with reference to the drawings, showing illustrative embodiments by way of example, not to be construed as limiting. The features described above are illustrative only and do not define limitations on various embodiments. Other features and benefits that characterize various embodiments will be apparent from the following detailed description, the associated drawings, and the other disclosure herein.

### BRIEF DESCRIPTION OF THE DRAWINGS

FIG. 1 shows a simulation of the distance distribution of Er³⁺ ions to the center of their nearest neighbouring nanocrystal, in accordance with an illustrative example.

FIGS. 2a-2c show space-separated quantum cutting in an erbium-silicon nanocrystal system, in accordance with an illustrative example.

FIG. 3 shows transients of erbium-related photoluminescence, in accordance with an illustrative example.

FIG. 4 shows Er-related photoluminescence photon flux dependence, in accordance with an illustrative example.

FIGS. 5a-5c show space-separated quantum cutting between silicon nanocrystals, in accordance with an illustrative example.

FIG. 6 shows the results of a simulation of the distribution of nearest neighbours for the solid-state dispersion of silicon nanocrystals in a SiO₂ matrix, in accordance with an illustrative example.

FIG. 7 shows a schematic of a photovoltaic device comprising a plurality of layers.

### DETAILED DESCRIPTION

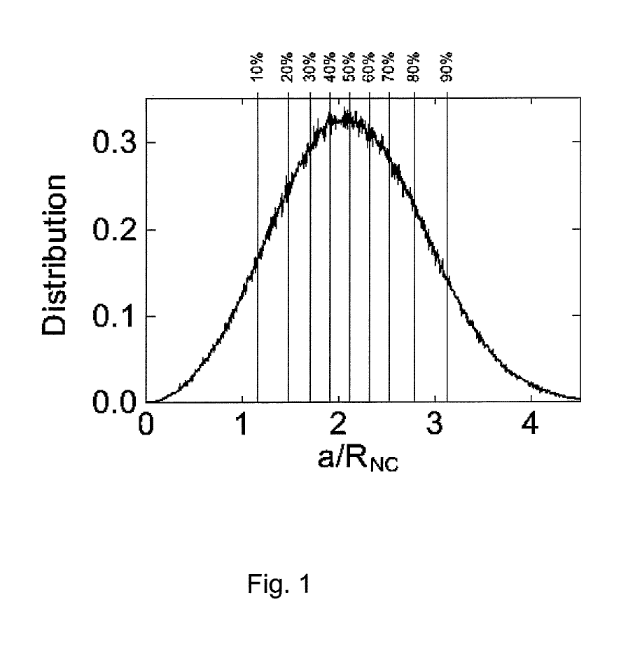

FIG. 1 shows a simulation of the distance distribution of Er³⁺ ions to the center of their nearest neighbouring nanocrystal assuming a random distribution of both: 6.6% of the Er³⁺ ions are contained inside nanocrystals.

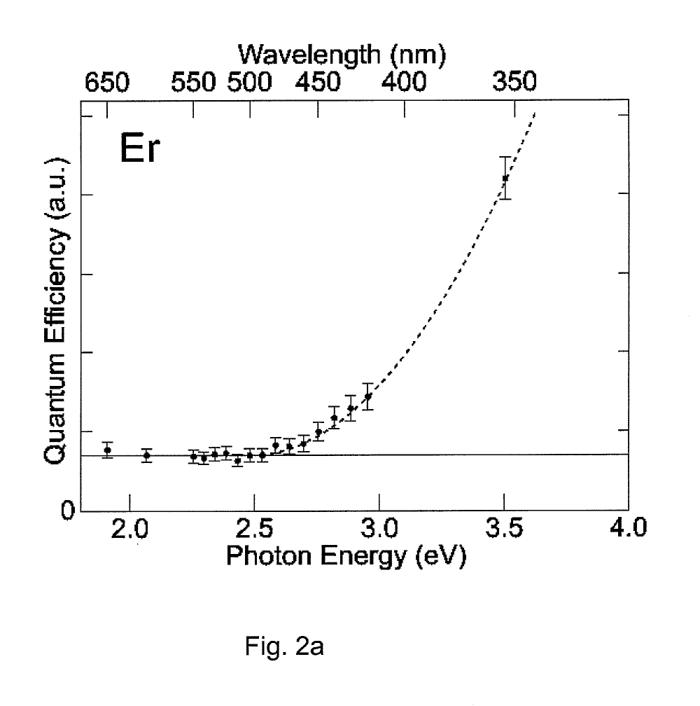

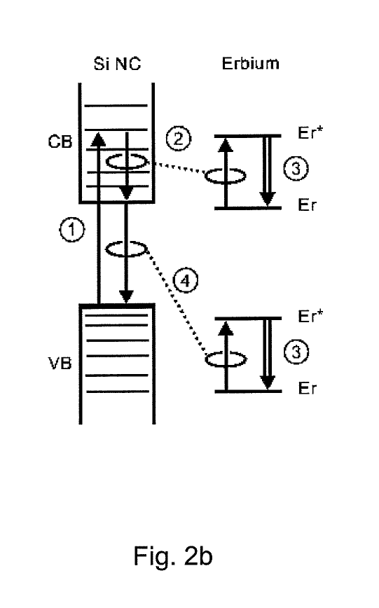

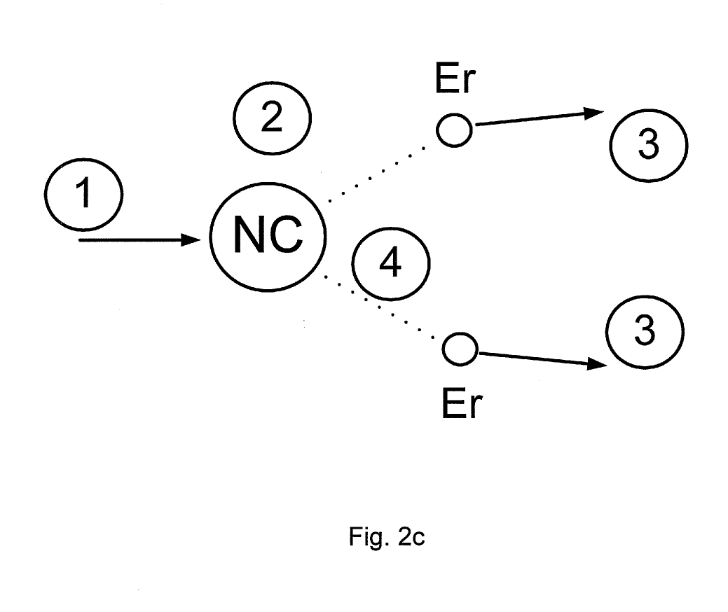

FIGS. 2a-2c show space-separated quantum cutting in an erbium-silicon nanocrystal system.

FIG. 2a shows the relative quantum efficiency of erbium-related photoluminescence (1,535 nm) as a function of excitation energy. The quantum efficiency is determined here as the ratio of the (effective) excitation cross-section of erbium photoluminescence and the absorbed fraction of incident photons, at a particular wavelength. For each data point the absorbed photon fraction was measured and the excitation cross-section was determined from the plot of photoluminescence intensity versus excitation photon flux. As can be seen, the quantum efficiency is constant up to a certain photon energy. This indicates a single-photon process: one photon in, one photon out. The relation deviates from constant for the excitation energy at which the space-separated quantum cutting (SSQC) process sets in, where there arises the possibility of emission of two photons per one absorbed photon. In this case, the energy of the incoming photon is divided by the excited nanocrystal over two nearby Er³⁺ ions. The solid line represents a fit to the data points, whereas the dashed line at higher energies is only a guide to the eye. The error bars reflect the uncertainty in the value of the power of the laser, 10% for optical parametric oscillators (OPO) and 15% for UV lasers, expressed as the standard deviation determined separately.

FIG. 2b is a schematic of the SSQC process and shows: 1, excitation of the silicon nanocrystal with a high-energy photon transferring an electron from the valence band (VB) to the conduction band (CB) creating a hot electron-hole pair with excess energy; 2, intraband Auger process exciting an Er³⁺ ion and removing the excess energy; 3, erbium-related photoluminescence; and 4, excitation of a second Er³⁺ ion by conventional interband Auger process.

FIG. 2c is a schematic illustrating the SSQC process with excitation of two nearby Er³⁺ ions.

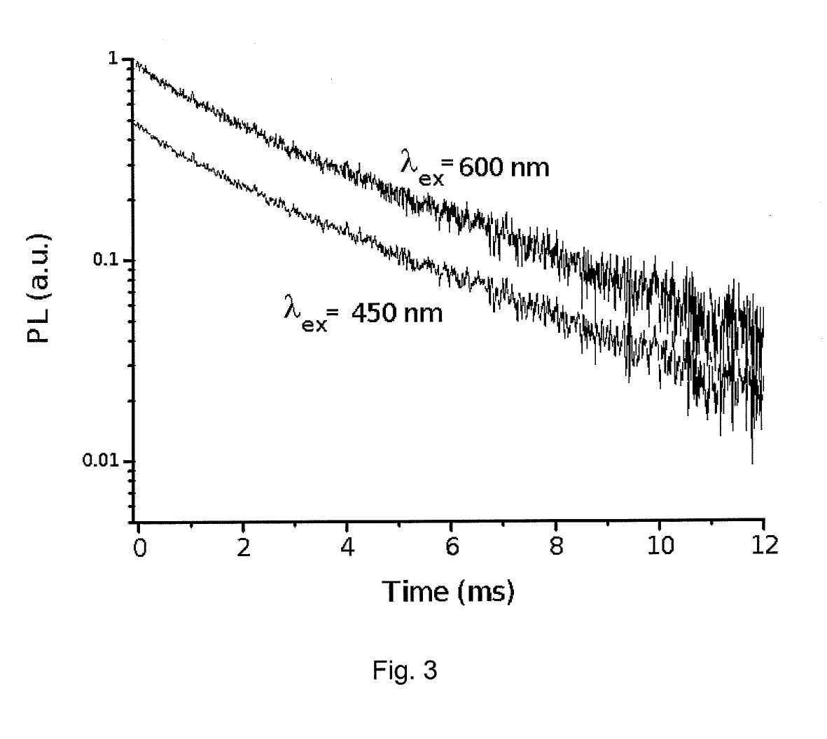

FIG. 3 shows transients of Er-related 1.5 μm photoluminescence measured at room temperature for excitation below (λₑₓ=600 nm) and above (λₑₓ=450 nm) the SSQC threshold. For easy comparison, the transient obtained with λₑₓ=600 nm has been multiplied by 2. Both transients show the same time decay.

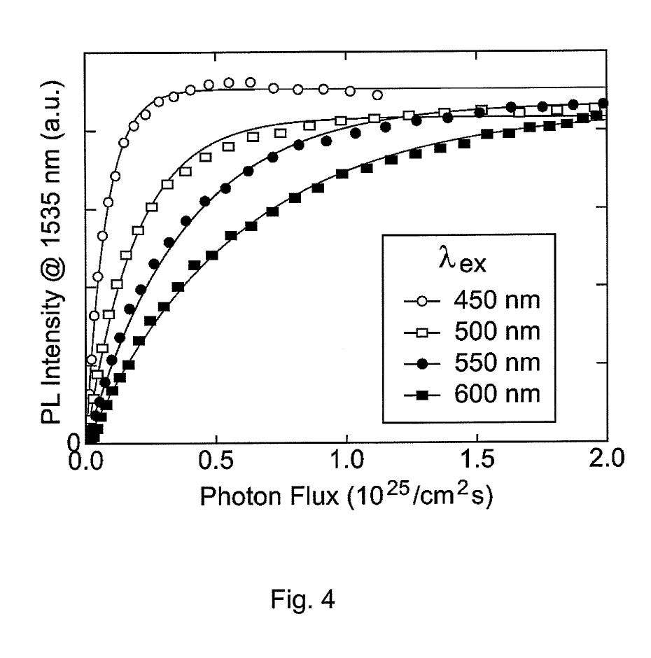

FIG. 4 shows Er-related photoluminescence photon flux dependence, i.e. dependence of the Er-related photoluminescence on the excitation photon flux, for different excitation wavelengths. Note that the saturation level is independent of the excitation wavelength.

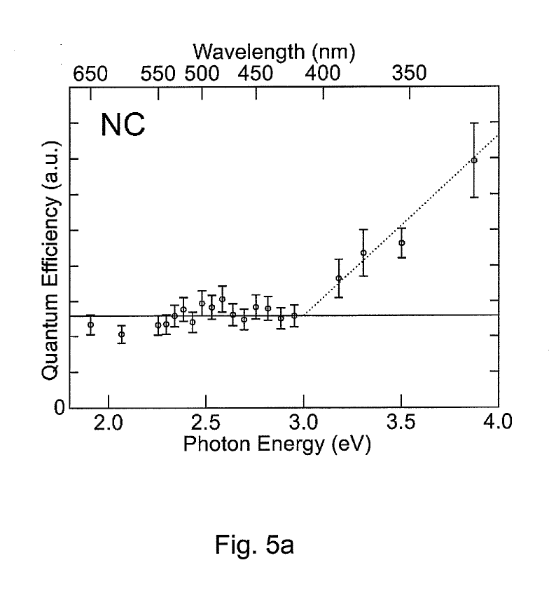

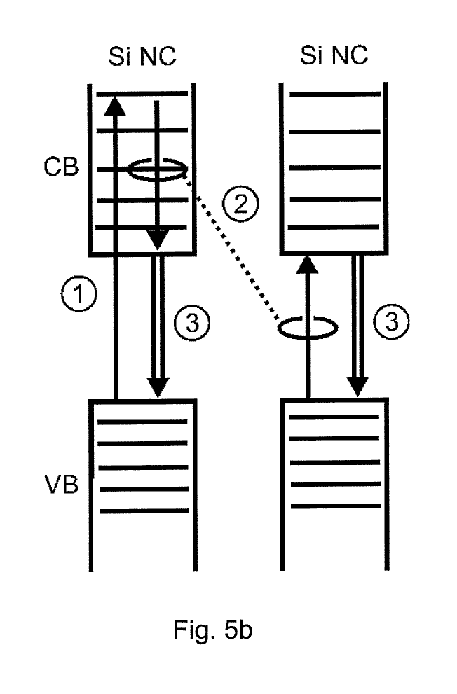

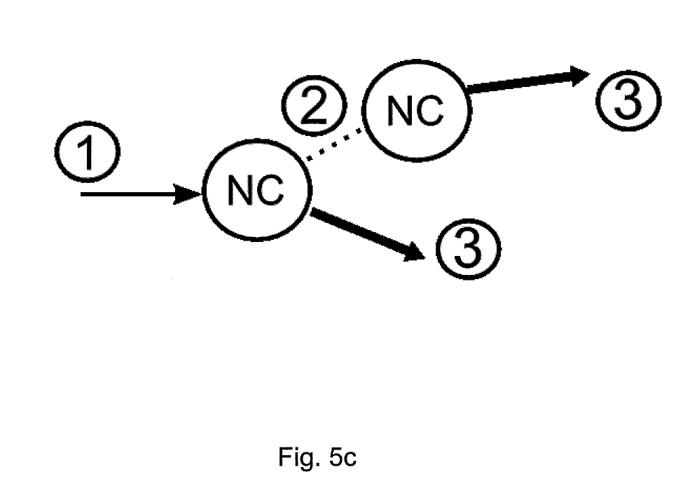

FIGS. 5a-5c show space-separated quantum cutting between silicon nanocrystals. Results are shown for an erbium-free solid-state dispersion of silicon nanocrystals in a SiO₂ matrix.

FIG. 5a shows the quantum efficiency of the nanocrystal-related photoluminescence (detected at 914 nm) as a function of excitation energy, illustrating that (neighbouring) nanocrystals can themselves also be the energy receiving systems. Quantum cutting appears at a larger energy than the incoming photon because the bandgap of silicon nanocrystals is larger than the erbium excitation energy, and a larger UV photon excess energy (hv-E_{NC}) is thus needed.

FIG. 5b is a diagram of the processes involved: 1, excitation of the silicon nanocrystal with a high-energy photon creating a hot electron-hole pair with excess energy; 2, intraband Auger process exciting a neighbouring nanocrystal, removing the excess energy; 3, nanocrystal exciton luminescence.

FIG. 5c shows a schematic of the process, showing one photon absorbed by a first nanocrystal, and two photons emitted by distinct first and second nanocrystals. FIG. 5c also represents a photovoltaic device, comprising an energy conversion material, wherein the energy conversion material comprises nanosized semiconductor quantum structures comprising a first quantum dot and a second quantum dot, in which the nanocrystals function as quantum dots.

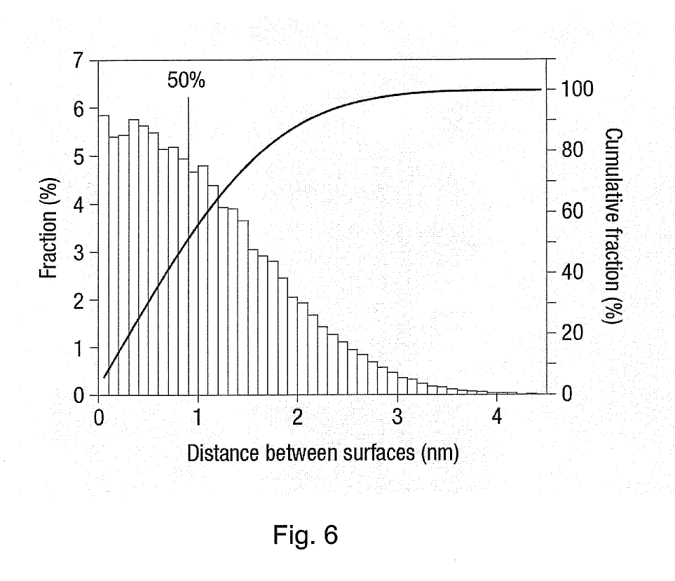

FIG. 6 shows the results of a simulation of the distribution of nearest neighbours for the solid-state dispersion of silicon nanocrystals in a SiO₂ matrix (erbium-free) investigated as an example. A histogram is depicted showing, with reference to the scale along the left side, the fraction of adjacent nanocrystals having the surface distance separations indicated along the x-axis, and showing a smooth curve with reference to the scale along the right-hand side indicating the cumulative fraction of adjacent nanocrystals that have a distance between their surfaces that is at or less than the indicated value. The separation distance between adjacent nanocrystals is approximately equal to or less than the average diameter of the nanocrystals. In this example more than 50% of the nanocrystals have a nearest neighbour within 1 nm of their surface. The separation of the first and second quantum dots is thereby of the same order of magnitude or smaller as the sizes of the quantum dots, in this illustrative example.

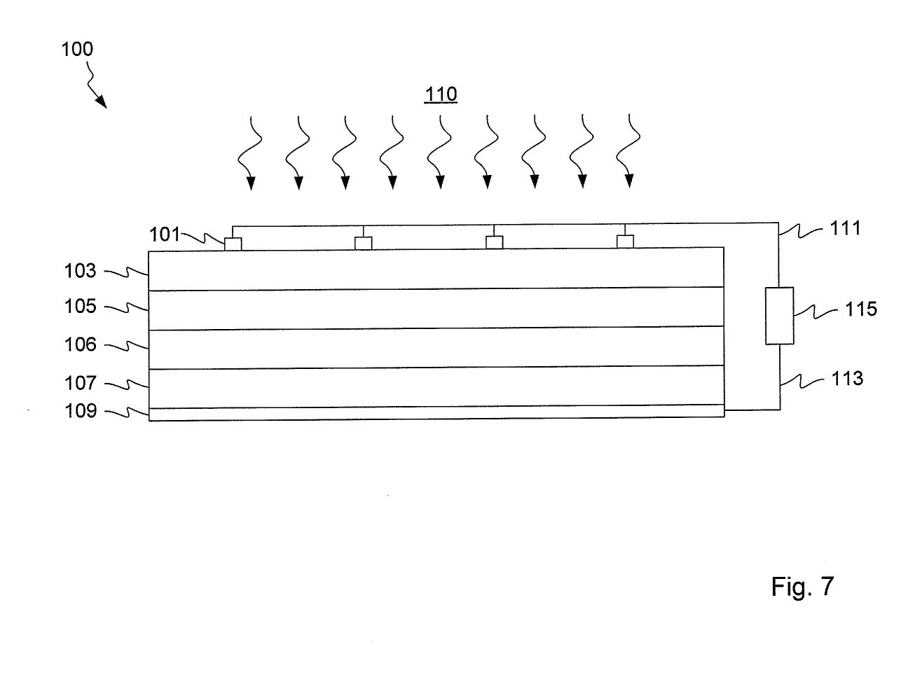

FIG. 7 shows a photovoltaic device 100 comprising a plurality of layers 101-109. The device comprises an anode in the form of a conductive layer 101, an N-type layer 103 for increasing conductivity of the device and promoting carrier extraction, a first energy conversion layer 105 comprising semiconductor nanostructures comprising quantum dots, a second energy conversion layer 106, a P-type conductive layer 107 for increasing conductivity of the device and promoting carrier extraction, and a cathode in the form of a conductive layer 109. At least one of the anode layer 101 and cathode layer 109 should be transparent and/or interspersed with gaps for allowing incident light to reach the energy conversion material. In the illustrative example of FIG. 7, at least the anode 101 is transparent and/or interspersed with gaps, the incident photons being generally indicated at 110. A suitable material for a transparent conductive layer for an electrode may comprise indium tin oxide (ITO), as an illustrative example.

Photovoltaic device 100 further comprises a first terminal 111 connected to anode 101 and a second terminal 113 connected to cathode 109, and both terminals 111, 113 connected to battery 115, thereby functioning as an apparatus configured to collect charge carriers, in accordance with this illustrative example. The terminals 111 and 113 may also be connected to an apparatus configured to use the charge carriers for a further process, such as operating an electrically driven tool, for example.

Further energy conversion layers may also be provided. Photovoltaic device may also include additional layers or components, illustratively such as anti-reflective coatings disposed on top of the surface of N-type layer 103 for reducing the amount of incident photons 110 lost to reflection, for example.

In the following example quantum cutting is described with respect to nanocrystals of silicon, still the most popular material for electronic and photovoltaic applications, embedded in a SiO₂ matrix as the energy conversion material. In the quantum-cutting process, energy can be transmitted to outside the photoexcited system. Quantum cutting proceeds in substantially similar fashion in other types of energy conversion materials comprising nanosized semiconductor quantum structures comprising a first quantum dot and a second quantum dot.

In a first experiment, Er³⁺ ions outside the nanocrystals were used as receptors for the down-converted energy, using their characteristic photoluminescence (PL) for detection of the phenomenon of quantum cutting.

Subsequently, it is demonstrated that a similar space-separated quantum cutting (SSQC) process takes place between silicon nanocrystals.

The experiments discussed below were conducted on 2-μm-thick films of silicon nanocrystals embedded in a SiO₂ matrix produced by sputtering on a quartz substrate. The silicon nanocrystals had an average diameter of about 3.1 nm with a size dispersion of 14% and a density of approximately 4.1×10¹⁸ cm⁻³. Larger nanocrystals, or nanosized semiconductor quantum structures in general, will lead to lower densities. The average distance between the surfaces of adjacent nanocrystals in the examples was about 3 nm, that is, their separation is about the same as the average nanocrystal diameter.

The studied material comprised layers. In the experiment discussed here, some of the layers were erbium-doped during sputtering to a concentration of 2.8×10¹⁹ cm⁻³. Assuming a random distribution of both Er³⁺ ions and silicon nanocrystals in the SiO₂ matrix, this means that about 6.6% of the dopants should be contained inside the nanocrystals and the rest dispersed in the SiO₂ (see FIG. 1).

The photoluminescence experiments were performed under pulsed excitation, provided in the visible range by a tunable optical parametric oscillator (OPO) pumped by a Nd:YAG laser (5 ns pulsewidth, 10 Hz repetition rate, 1-10 mJ per pulse), and in the UV range by the third harmonic of a Nd:YAG or dye laser pumped by a XeCl (308 nm) excimer laser. The wavelength of the photoluminescence was selected with a monochromator and detected with a Hamamatsu RS509-72 near-IR photomultiplier tube or a germanium photodiode (Edinburgh Instruments EI-A) connected to a digital oscilloscope where signal integration was carried out. The emerging emission was monitored at wavelengths of 1535 nm and 914 nm for the erbium and nanocrystal-related photoluminescence, respectively. Signal integration was performed over the entire photoluminescence decay-time window (typically from between 1 ms and a few milliseconds for nanocrystal- and erbium-related photoluminescence, respectively); the recorded photoluminescence intensity value therefore predominantly reflects the contributions of relatively slow radiative processes. In particular, for the erbium-related emission, only the approximately millisecond component due to Er³⁺ ions in SiO₂ is accounted for, with the contribution from fast-decaying dopants being negligible. A Varian Cary-50 UV-VIS spectrophotometer was used for absorption measurements in the visible and the UV regions. All measurements were performed at room temperature.

In the first experiment the erbium-related photoluminescence was monitored as a function of excitation wavelength and compared to the absorption of the sample at that wavelength.

At the start of a cycle, the nanocrystal absorbs a photon and an electron-hole pair is created. On its recombination, one relaxation path will transfer the energy to a neighbouring Er³⁺ ion, placing it in an excited state. Subsequently, the Er³⁺ ion relaxes back to the ground state by emitting a long-wavelength (IR) photon, which can be detected as photoluminescence at 1535 nm.

This process implies that, indeed, the erbium-related photoluminescence should be correlated to photon absorption by silicon nanocrystals. It should be mentioned that under the present experimental conditions no direct absorption by erbium takes place, and therefore any erbium-related emission must originate from photon absorption in silicon nanocrystals. From this it follows that the total number of photons emitted (by erbium) should be correlated to the total number of photons absorbed (by silicon nanocrystals).

To describe this, the photoluminescence quantum efficiency η is introduced, which is defined as the ratio of the number of photons coming out of the sample N_{PL} to the number of photons absorbed N_{abs}:

η=N_{PL}/N_{abs}.

Because, in the used set-up, the luminescence intensity is not calibrated and its absolute value cannot be measured, the absolute values of this efficiency cannot be determined. Nevertheless, the relative efficiency enables direct comparison of the different mechanisms leading to emission, in the same system investigated and in the same set-up, as reported here.

FIG. 2a shows the experimentally measured quantum efficiency of erbium-based photoluminescence. Each data point in the figure represents the ratio of the photoluminescence excitation cross-section to the fraction of absorbed photons for a particular wavelength of the incoming light (see Appendix for a detailed derivation of the relative quantum efficiency). In each case, the photoluminescence excitation cross-section was determined from the slope of the plot of photoluminescence intensity versus laser photon flux in the linear region. In this way, the effective excitation cross-section of erbium emission at different wavelengths can be compared, which is relevant for analysis of the experiment.

The wavelength dependence of the fraction of the incident light that is absorbed by the sample is measured in a separate experiment.

For a single-photon generation process, the correlation between the number of absorbed photons and emitted photons is linear and the ratio constant: with a certain efficiency a long-wavelength photon is emitted by the Er³⁺ ion for every short-wavelength photon absorbed by the silicon nanocrystal. From FIG. 2a it is evident that this scenario is indeed followed for the lower range of excitation energies. However, a clear enhancement is seen for photon energies above a certain threshold, about 2.6 eV (corresponding to a wavelength of about 480 nm). At this energy, the quantum efficiency of the energy transfer to erbium increases, as double-photon generation kicks in at this point.

The process is schematically illustrated in FIG. 2b; the excess energy ΔE of the ‘hot’ carrier (ΔE=hv−E_{NC}, where hv and E_{NC} are photon and exciton energies, respectively) is large enough to allow for an Auger process of intraband relaxation with simultaneous erbium excitation. As a result, two Er³⁺ ions can be excited per single photon absorbed by the nanocrystal, with the second resulting from a conventional band-to-band Auger process, as indicated in the schematic.

Analysing the energy diagram in FIG. 2b, such a process is expected for photon energies exceeding the sum of the silicon nanocrystal bandgap (about 1.5 eV) and the erbium excitation (0.8 eV), thus above about 2.3 eV. Note that the decay time and also the saturation level of erbium-related photoluminescence are identical for pumping below-threshold and above-threshold, see FIGS. 3 and 4.

The above-described experiment concerning erbium excitation by silicon nanocrystals thus illustrates the SSQC process with an Er³⁺ ion serving as a receptor of the down-sized energy quanta.

It has been found that part of the energy can also be transferred to create an exciton in a neighbouring nanocrystal by converting a high-energy (UV) photon absorbed in one of them. A significant condition appears to be that these nanocrystals are located within the energy transfer range, which condition is met when the nanocrystals involved are arranged at a separation of the same order of magnitude as their diameters or smaller.

To demonstrate this process, the same experiment is repeated for a sample without erbium doping, correlating the silicon nanocrystal-related exciton photoluminescence, monitored at 914 nm, with the absorbed photon fraction.

The results are illustrated in FIGS. 5a-5c. Again, a constant ratio is observed, which, in this case, extends to a larger energy range.

This was anticipated, as double-photon generation is expected only for photons with quantum energy at least twice that of the nanocrystal bandgap, hv>2E_{NC}≈3 eV. In full agreement with this expectation, it may be appreciated that the data obtained in the UV range fall clearly outside the dependence determined for low-energy excitation.

This result shown in FIGS. 5a-5c demonstrates that the nanocrystals themselves can also be the receiving elements in the SSQC process, albeit here at higher energies. In other words, a second silicon nanocrystal can be excited by a neighbouring first silicon nanocrystal containing a hot electron-hole pair. The partly de-excited first silicon nanocrystal will still be able to produce photoluminescence owing to the ‘cold’ electron-hole pair (exciton).

Thus, when the energy of the incident photon exceeds a certain threshold, relaxation back to the ground state can occur through emission of two photons in the silicon nanocrystal exciton photoluminescence wavelength range.

Without wishing to be bound to a specific theory, a possible physical mechanism behind the SSQC phenomenon will now be discussed. As pointed out previously, the SSQC bears close resemblance to the multiple exciton generation process in which two, or more, electron-hole pairs are induced in one nanocrystal on absorption of a single photon. The microscopic origin of multiple exciton generation is under debate and several possibilities have been suggested:

(1) Impact ionization by a hot carrier created as the result of the photon absorption.

(2) Coherent superposition of single and multiexciton states due to the strong Coulomb interaction of carriers confined in nanocrystals, which should take place when the energy relaxation rate of a single electron-hole pair is lower than both the two-exciton state thermalization rate and the rate of Coulomb coupling between single- and two-exciton states.

(3) Multiexciton formation through a virtual state. This process can be described by second-order perturbation theory, and two possible scenarios, with comparable rates, have been proposed. The first proceeds through a virtual single-exciton state. In this case, the direct optical transition from vacuum to a single-exciton state is followed by a transition into the final two-exciton state owing to Coulomb interaction. In the second channel, the first step is the transition initiated by the Coulomb interaction from vacuum to a two-exciton state, and the second step is an optical intraband transition.

Processes 1 and 2 can be responsible for multiple exciton generation without any delay, that is, the instant a photon is absorbed, and can be effective for the production of multiple excitons in a single nanocrystal.

However, extra excitons occurring in the same nanocrystal may recombine on a picosecond timescale.

The impact ionization process (1) starts with some delay after the absorption. It proceeds through a real state, when the hot electron-hole pair is created by the absorbed photon with energy exceeding the energy gap. This process is well known for bulk semiconductors, where it increases the number of photoexcited excitons by less than about 1%. It may be expected that the impact ionization rate should rise dramatically in the case of nanocrystals owing to the strong Coulomb interaction of confined carriers and the decreasing rate of phonon emission caused by the discrete spectrum. Indeed, pseudopotential calculations predict a higher rate of impact ionization in CdSe dots than in bulk material for electrons with excess energies just above the bottom of the conduction band.

Preliminary theoretical considerations indicate that impact ionization is the most suitable process to account for the present SSQC phenomenon. The effective dielectric constant governing the Coulomb interaction between carriers in different nanocrystals embedded in the SiO₂ matrix is considerably smaller than the dielectric constant of silicon. Using the calculated Auger recombination rate (the reverse process to impact ionization) inside the silicon nanocrystal, a value of the order of between 10¹⁰ and 10¹¹ s⁻¹ is obtained for the rate of the process under consideration for two nanocrystals separated by a distance of less than 1 nm. This rate is comparable to the energy relaxation rate determined by the Auger process between carriers confined in one silicon nanocrystal of 3 nm diameter when there is one exciton per nanocrystal. From the nanocrystal-NC distance distribution depicted in FIG. 3, it is concluded that more than 50% of all nanocrystals have their closest neighbour at a distance of less than 1 nm from the surface, that is, more than sufficiently close to facilitate the proposed energy transfer. It is worth mentioning that for direct-bandgap nanocrystals, faster cooling rates, of the order of 10¹² s⁻¹, are commonly reported. Hence, indirect-bandgap materials are considered beneficial for the presently disclosed device and method.

Note that the observed linear increase of SSQC quantum efficiency for photon energies higher than the threshold value, experimentally observed in the examples studied here for silicon nanocrystals (FIG. 5a) is in agreement with the calculated linear increase of the number of final states and therefore supports the microscopic mechanism based on impact ionization. Yet additional support comes from measurements performed in a sample with a similar erbium concentration and nanocrystal size, but with a lower nanocrystal concentration, that is, with a larger erbium-NC separation. In this case the observed SSQC process shows a similar onset energy but lower quantum efficiency, providing an independent verification of the proposed mechanism.

For completeness, it should be recalled that the Förster resonant energy transfer (FRET), which has been shown to be responsible for long-range energy diffusion in a closely packed CdSe quantum solid, has a low probability of occurring for silicon nanocrystals owing to the indirect bandgap.

It is nevertheless fair to mention that the final identification of the microscopic mechanism of the SSQC process (as well as that of multiple exciton generation) may require further investigation for a more thorough theoretical understanding. This, however should not affect the usefulness of the presently disclosed devices and methods.

In summary, it is shown that quantum cutting (one photon in, plural photons out or plural sets of charge carriers out) can take place in systems based on silicon nanocrystals, in various illustrative embodiments.

It should be noted here that the same effect of SSQC may also be achieved by a first and a second photon together exciting the first quantum dot, which first and a second photons in combination have a total energy of more than the sum of the first and second bandgaps of the first and second quantum dots involved, whereas each involved individual photon of the first and second photons may have insufficient energy for instigating the process. The individual photon energies of the involved first and second photons need not be equal.

The above treatise is considered to be valid mutatis mutandis to other optical energy conversion materials comprising nanosized semiconductor quantum structures comprising a first quantum dot and a second quantum dot, the first quantum dot having a first size and a first bandgap, the second quantum dot having a second size and a second bandgap, wherein the separation of the first and second quantum dots is of the same order of magnitude as the first or second size or smaller.

The energy quanta down-converted in the SSQC process are transferred to external objects—Er³⁺ ions and neighbouring nanocrystals—from where they can be emitted in the form of photons, or harvested in a different manner such as by separation into independent charge carriers.

In this way, true space-separated photon cutting takes place. Although applicable to other systems, the demonstration of the SSQC process for silicon is particularly technologically interesting in view of the prominent role of silicon and silicon-derived materials in electronic, optoelectronic and especially photovoltaic applications.

It should be appreciated that, whereas the experimental evidence presented above was produced with pulsed light, the SSQC process is substantially independent of pulsed or (semi-) continuous light. The presently presented device and method are therefore very well suited also for use with substantially continuous illumination, e.g. for use in photovoltaic energy converters for prolonged use such as solar cells.

Moreover, the use of nanocrystals provides the additional appealing feature that the energy levels of one or more of the nanocrystals can be tuned to suit the application by changing the size of the particles.

Also, the efficiency of the SSQC process can be adjusted by changing the separation between individual nanocrystals. The ideas and results presented here may comprise substantial improvements in photovoltaic devices, both solar cells and light emitting elements. In an illustrative embodiment, a quantum cutting photovoltaic device may also include an anode, a cathode and an apparatus configured to collect charge carriers connected to said anode and said cathode, where such apparatus can be any known in the art. The incident photonic energy may thereby be translated into current and collected as useful energy.

For solar cells it is shown theoretically that multiple exciton generation and photon down-conversion can increase the efficiency beyond the Shockley-Queisser limit.

Interestingly, the indirect nature of the silicon bandgap, which is preserved in silicon nanocrystals, and which is detrimental to most photonic applications, turns out to be beneficial here, as the relatively long exciton lifetime (in comparison with direct-bandgap nanocrystals) simplifies energy extraction for photovoltaic applications. This effect of an indirect bandgap is also considered to be usable to advantage with other energy conversion materials of the above-described types.

Although the subject matter has been described in language specific to structural features and/or methodological acts, it is to be understood that the subject matter defined in the appended claims is not necessarily limited to the specific features or acts described above as has been determined by the courts. Rather, the specific features and acts described above are disclosed as illustrative examples of implementing the claims.

### APPENDIX

### The Relative Quantum Efficiency

In absorption measurements, the intensity of light transmitted through a sample is given by

I₁=I₀exp(−αL), (1)

where I₀ is the incident intensity, L is the sample thickness, and α is the absorption coefficient. (For this analysis, the reflection of the sample is neglected; in any case, wavelength-independent reflection will not influence the conclusion). The fraction of photons that are absorbed from the beam, the absorbance signal S_{abs}, is thus:

S_{abs}=(I₀−I₁)/I₀=1exp(−αL), (2)

and ranges from 0 (full transmission) to 1 (full absorption). The number of photons absorbed per pulse is then equal to the number of photons incident on the sample (given by the product of the incident laser beam area A, the photon flux φ, and the laser pulse length Δt), and the fraction given above:

N_{abs}=φΔtAS_{abs}. (3)

(Measurements of absorption are performed at low intensity to avoid non-linear effects such as double-photon absorption). If photoluminescence occurs with an efficiency η, the number of photons emitted after each pulse is

N_{PL}=ηN_{abs}=ηφΔtAS_{abs}. (4)

The luminescence signal S_{PL} is proportional to the number of photons emitted:

S_{PL}=χN_{PL}=χηφΔtAS_{abs}, (5)

where the factor χ is a function of the geometry of the setup, the efficiency of the photo detector, etc. Here, the photoluminescence yield Y_{PL} is defined as the derivative of the photoluminescence intensity vs. flux:

Y_{PL}≡ds_{PL}/dφ=χηAΔtS_{abs}, (6)

and the ratio of luminescence yield and the absorbance signal is given by

Y_{PL}:S_{abs}=ηχΔtA. (7)

The above formula (7) contains only constants, except for η, which can depend on the wavelength.

When changing to another setup, χ, Δt, and A can change. However, in order to be able to compare data from different setups, the measurements can be auto-calibrated on the saturation behavior. The saturation of photoluminescence intensity on increase of flux can be described as follows: The number of emitters (here, Si nanocrystals or Er³⁺) in the excited state that contribute to photoluminescence under illumination during the laser pulse, N*, is governed by simple kinetics:

dN*/dt=φ_{PL}φ(N−N*)−N*/τ, (8)

where t is time, N is the number of excitable units (in this case proportional to the number of nanocrystals or Er³⁺ in the area under illumination), τ is the relaxation time, and σ_{PL} is the photoluminescence excitation cross-section. When the laser pulse length Δt is short compared to τ, as is the case in the experiments presented here, the second term, describing de-excitation, can be ignored. The solution, when allowing only for single photoluminescence excitation (one photon can produce only one excitation in the emitting center), is then given by:

N*=N[1−exp(−σ_{PL}φΔt)]. (9)

By definition, the number of photons emitted is equal to N*, when only radiative recombination is considered, and proportional to N*, when also non-radiative recombination is allowed. It is assumed here that maximum one exciton per nanocrystal can contribute to photon generation. It is well established that a strong Auger quenching takes place between excitons located within the same Si nanocrystal. Consequently, in case that multiple excitons per nanocrystal are generated during the laser pulse, only one of them will survive the non-radiative recombination, and contribute a photon to the photoluminescence signal, either by emitting a photon (nanocrystal-related photoluminescence) or by transferring its energy to dopant (Er-related photoluminescence). This assumption is directly confirmed by the fact that the photoluminescence intensity saturation level is independent of the excitation wavelength—see FIG. 4 for the photon flux dependence of Er-related photoluminescence intensity. The time-integrated photoluminescence signal after excitation is then proportional to N*, which thus saturates upon increase of photon flux φ:

S_{PL}=χN_{PL}=χN*=χN[1−exp(−σ_{PL}φΔt)]. (10)

The photoluminescence excitation cross-section σ_{PL} (and the product χN) can be determined by fitting the measured photoluminescence intensity dependence on photon flux, also shown in FIG. 6. In particular, it is noted that at infinite flux and small flux the above equation gives, respectively:

S_{PL,max}=χN, (11a)

Y_{PL}≡dS_{PL}/dφ|_{φ→0}=χNσ_{PL}Δt. (11b)

Comparison of Eq. 6 with the last equation shows that N σ_{PL}=ηS_{abs}. In other words, the quantum efficiency is linked to the experimentally measured parameters as:

η=Nσ_{PL}/S_{abs}. (12)

Because knowledge of N cannot be obtained (only the product χN can be determined by fitting), only the relative quantum efficiency can be determined and is proportional to the ratio of the fitting parameter σ_{PL} and the measured absorbance signal S_{abs}.

The fact that the photoluminescence saturation level is independent of excitation wavelength, i.e., S_{PL,max} is independent of λₑₓ, implies that N is a constant not depending on λₑₓ. Thus, plotting the ratio of photoluminescence cross-section and absorbance signal will directly provide information about the relative quantum efficiency η.

This method has been used for preparation of FIGS. 2a and 5a.

What is claimed is:

1. A photovoltaic device, comprising an energy conversion material, wherein the energy conversion material comprises nanosized semiconductor quantum structures comprising a first quantum dot and a second quantum dot,
the first quantum dot having a first size,
the second quantum dot having a second size,
wherein the separation of the first and second quantum dots is of the same order of magnitude as the first or second size or smaller,
such that, by irradiating the first quantum dot with a photon for producing one or more excitons in the first quantum dot, one or more further excitons are also produced in the second quantum dot.

2. The photovoltaic device according to claim 1, wherein the energy conversion material comprises nanosized semiconductor quantum structures having an indirect bandgap.

3. The photovoltaic device according to claim 1, wherein the energy conversion material comprises nanosized semiconductor quantum structures comprising quantum dots dispersed throughout at least a portion of the energy conversion material at a density of more than about 10¹⁶ cm⁻³.

4. The photovoltaic device according to claim 1, wherein the energy conversion material comprises semiconductor nanocrystals.

5. The photovoltaic device according to claim 4, wherein the energy conversion material comprises at least one of silicon nanocrystals and germanium nanocrystals.

6. The photovoltaic device according to claim 5, wherein the energy conversion material comprises semiconductor nanocrystals in silicon oxide.

7. The photovoltaic device according to claim 4, wherein the energy conversion material comprises semiconductor nanocrystals in silicon oxide.

8. The photovoltaic device according to claim 1, wherein the energy conversion material comprises a plurality of layers, at least one of the layers comprising the nanosized semiconductor quantum structures.

9. The photovoltaic device according to claim 1, wherein at least one of the first size and the second size is configured for providing energy levels corresponding to a desired photon energy.

10. The photovoltaic device according to claim 1, further comprising an anode, a cathode and an apparatus configured to collect charge carriers connected to said anode and said cathode.

11. A method of converting optical energy using an energy conversion material comprising nanosized semiconductor quantum structures comprising a first quantum dot and a second quantum dot,
the first quantum dot having a first band gap,
the second quantum dot having a second band gap;
the method comprising the step of irradiating the first quantum dot with a photon having a photon energy of at least the sum of the first band gap and the second band gap to produce a first exciton in the first quantum dot and a second exciton in the second quantum dot.

12. The method of claim 11, comprising separating at least one of said first and second excitons into charge carriers, and collecting a current generated by said charge carriers between an anode and a cathode.

13. The method of claim 11, comprising de-exciting at least one of the first and second excitons by emission of a photon.

14. The method of claim 13, comprising using said emitted photon for exciting a photovoltaic energy conversion material.

15. A method of manufacturing an energy conversion material comprising nanosized semiconductor quantum structures comprising quantum dots dispersed throughout at least a portion of the energy conversion material at a density of more than about 10¹⁶ mm⁻³
such that, by irradiating a first quantum dot of said quantum dots with a photon for producing one or more excitons in said first quantum dot one or more further excitons are also produced in an adjacent second quantum dot of said quantum dots.

16. The method according to claim 15, comprising the step of adapting one or more process steps for obtaining at least some quantum dots within the energy conversion material having a size configured for providing energy levels corresponding to a desired photon energy.

17. The method according to claim 15, wherein the energy conversion material is provided as one layer of a plurality of layers.
